(19) United States
(12) Patent Application Publication
(10) Pub. No.: US 2015/0091055 A1
(43) Pub. Date: Apr. 2, 2015

(54) SEMICONDUCTOR DEVICE

(71) Applicant: KABUSHIKI KAISHA TOSHIBA, Tokyo (JP)

(72) Inventors: Ryohei GEJO, Kanagawa (JP); Kazutoshi NAKAMURA, Hyogo (JP); Tsuneo OGURA, Kanagawa (JP); Tomoko MATSUDAI, Tokyo (JP)

(73) Assignee: KABUSHIKI KAISHA TOSHIBA, Tokyo (JP)

(21) Appl. No.: 14/194,374

(22) Filed: Feb. 28, 2014

(30) Foreign Application Priority Data
Oct. 1, 2013 (JP) 2013-206742

(51) Int. Cl. H01L 29/739; H01L 29/10

(52) U.S. Cl. CPC H01L 29/7395; H01L 29/1095
USPC 257/142; 257/139

(57) ABSTRACT

A semiconductor device includes a first region of a first conductivity type, a collector electrode electrically connected to a first side of the first region, first and second gate electrodes and first and second conductor electrodes, each of the gate and conductor electrodes extending into the first region from a second side thereof that is opposite to the first side, an emitter electrode electrically connected to the conductor electrodes, and a second region of the first conductivity type, that is adjacent to the gate electrodes, electrically connected to the emitter electrode, and spaced from the first and second conductor electrodes.

### CROSS-REFERENCE TO RELATED APPLICATION

This application is based upon and claims the benefit of priority from Japanese Patent Application No. 2013-206742, filed Oct. 1, 2013, the entire contents of which are incorporated herein by reference.

### FIELD

Embodiments described herein relates generally to a semiconductor device.

### BACKGROUND

Recently, an IGBT (Insulated Gate Bipolar Transistor) has been popularly used as a power semiconductor device which has a high breakdown voltage and can handle a large electric current. The IGBT is used as a switching element in general. In the semiconductor device formed of an IGBT, there has been a need for higher speed switching.

### DESCRIPTION OF THE DRAWINGS

FIG. 1 is a schematic cross-sectional view of a semiconductor device according to a first embodiment.

FIG. 2 is a schematic cross-sectional view of a semiconductor device according to a second embodiment.

FIG. 3 is a schematic cross-sectional view of a semiconductor device according to a third embodiment.

FIG. 4 is a schematic cross-sectional view of a semiconductor device according to a fourth embodiment.

FIG. 5 is a schematic cross-sectional view of a semiconductor device according to a fifth embodiment.

FIG. 6 is a schematic cross-sectional view of a semiconductor device according to a sixth embodiment.

FIG. 7 is a schematic cross-sectional view of a semiconductor device according to a seventh embodiment.

FIG. 8 is a schematic cross-sectional view of a semiconductor device according to an eighth embodiment.

FIG. 9 is a schematic cross-sectional view of a semiconductor device according to a ninth embodiment.

FIG. 10 is a schematic cross-sectional view of a semiconductor device according to a tenth embodiment.

### DETAILED DESCRIPTION

Embodiments provide a semiconductor device that can achieve high-speed switching.

In general, according to one embodiment, a semiconductor device includes a first region of a first conductivity type, a collector electrode electrically connected to a first side of the first region, first and second gate electrodes and first and second conductor electrodes, each of the gate and conductor electrodes extending into the first region from a second side thereof that is opposite to the first side, an emitter electrode electrically connected to the conductor electrodes, and a second region of the first conductivity type, that is adjacent to the gate electrodes, electrically connected to the emitter electrode, and spaced from the first and second conductor electrodes.

According to another embodiment, a semiconductor device includes: a first semiconductor region; a plurality of control electrodes; a plurality of conductive portions; a second semiconductor region; a third semiconductor region; a fourth semiconductor region; a fifth semiconductor region; a first insulation film; a second insulation film; a first electrode; and a second electrode.

The first semiconductor region is a region of a first conductive type.

The plurality of control electrodes are formed on the first semiconductor region, and are separated from each other in a first direction.

The plurality of conductive portions are formed between a first control electrode and a second control electrode adjacent to the first control electrode out of the plurality of control electrodes.

The second semiconductor region is a region of a second conductive type formed on the first semiconductor region.

The third semiconductor region is a region of a first conductive type formed on the second semiconductor region.

The fourth semiconductor region is a region of a first conductive type formed between the first semiconductor region and the second semiconductor region.

The fifth semiconductor region is a region of a second conductive type formed on the first semiconductor region on a side opposite to the second semiconductor region.

The first insulation film is formed between the plurality of respective control electrodes and the first semiconductor region, the second semiconductor region, the third semiconductor region and the fourth semiconductor region.

The second insulation film is formed between the plurality of respective conductive portions and the first semiconductor region, the second semiconductor region and the fourth semiconductor region.

The first electrode is conductive with the second semiconductor region, the third semiconductor region and the plurality of conductive portions.

The second electrode is conductive with the fifth semiconductor region.

Hereinafter, embodiments are explained with reference to drawings. The semiconductor devices are schematically or conceptually shown in the drawings and hence, the relationship between thicknesses and widths, a ratio of size between portions and the like are not always equal to those of an actually manufactured semiconductor device. Further, even when the same portion is described in several drawings, there may be a case where the portion is described with different sizes or with different ratios depending on drawings.

Further, in the disclosure and respective drawings, elements of an embodiment substantially the same as those previously explained with reference to other drawings are given same symbols, and the repeated explanation of these parts is omitted.

In the explanation made hereinafter, indications n⁺, n, n⁻ and p⁺, p, p⁻ indicate the relative degrees of concentrations of dopant of respective conductive types. That is, “n⁺” indicates that a portion denoted as “n⁺” has a higher concentration of n-type dopant, as compared to a portion denoted as “n”, and “n⁻” indicates that a portion denoted as “n⁻” has a lower concentration of n-type dopant as compared to a portion denoted as “n”. In the same manner, “p⁺” indicates that a portion denoted as “p⁺'” has a higher concentration of p-type dopant, as compared to a portion denoted as “p”, and “p⁻” indicates that a portion denoted as “p⁻” has a lower concentration of p-type dopant, as compared to a portion denoted as “p”.

In the explanation made hereinafter, a specific example is explained where a first conductive type is set as an n type, and a second conductive type is set as a p type.

### First Embodiment

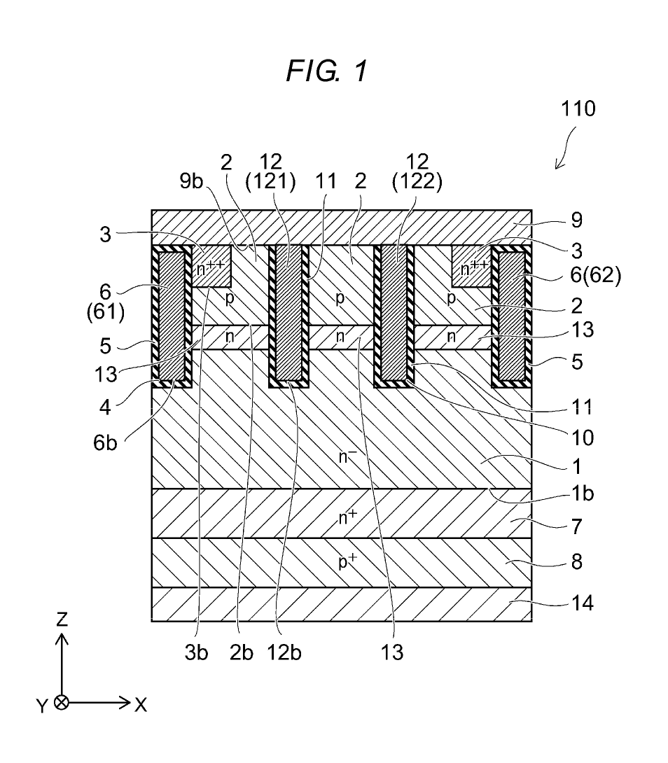

FIG. 1 is a schematic cross-sectional view of a semiconductor device according to the first embodiment.

As shown in FIG. 1, a semiconductor device 110 according to this embodiment includes: an n⁻-type base region (first semiconductor region) 1; a plurality of gate electrodes (control electrodes) 6; a plurality of conductive portions 12; a p-type base region (second semiconductor region) 2; an n⁺⁺-type emitter region (third semiconductor region) 3; an n-type barrier region (fourth semiconductor region) 13; a p⁺-type collector region (fifth semiconductor region) 8; a gate insulation film (first insulation film) 5; an emitter insulation film (second insulation film) 11; an emitter electrode (first electrode) 9; and a collector electrode (second electrode) 14. The semiconductor device 110 is an IGBT, for example.

In the embodiment explained hereinafter, it is assumed that the direction along which the n⁻-type base region 1 and the p-type base region 2 are connected to each other is the Z direction, that one of the directions orthogonal to the Z direction is the X direction, and that the direction orthogonal to the Z direction and the X direction is the Y direction.

The plurality of gate electrodes 6 are formed on the n⁻-type base region 1. The plurality of gate electrodes 6 are arranged with separation therebetween in the X direction. Although two gate electrodes 6 are shown in FIG. 1, three or more gate electrodes 6 may be formed in the semiconductor device 110. In the explanation made hereinafter, it is assumed that out of the plurality of gate electrodes 6, two gate electrodes 6 adjacent to each other are a first gate electrode 61 and a second gate electrode 62 respectively. The gate electrodes 6 extend in the Y direction, for example.

The gate electrodes 6 are formed in gate trenches 4 which are formed in such a manner that the gate trenches 4 penetrate the p-type base region 2 and the n-type barrier region 13 and reach an intermediate portion of the n⁻-type base region 1, i.e., they extend into, but not through, the n⁻-type base region 1. Due to the formation of the gate trenches 4, recessed portions are formed in the p-type base region 2, the n-type barrier region 13 and the n⁻-type base region 1.

A semiconductor material (for example, polycrystalline silicon) doped with a dopant is used as the gate electrode 6 material, for example. A metal may alternatively be used to form the gate electrode 6.

The plurality of conductive portions 12 are formed between the first gate electrode 61 and the second gate electrode 62. In an example shown in FIG. 1, two conductive portions 12 are formed between the first gate electrode 61 and the second gate electrode 62. The conductive portions 12 also extend in the Y direction, for example.

Three or more conductive portions 12 may be formed. In the explanation made hereinafter, when n (n being a positive integer) conductive portions 12 are formed, the conductive portions 12 are named as the first conductive portion 121, the second conductive portion 122, . . . , the n-th conductive portion 12n in order from the first gate electrode 61 toward the second gate electrode 62. In the example shown in FIG. 1, the first conductive portion 121 is formed to be adjacent to the first gate electrode 61, and the second conductive portion 122 is formed to be adjacent to the second gate electrode 62.

The conductive portions 12 are formed in emitter trenches 10 which are formed such that the emitter trenches 10 penetrate the p-type base region 2 and the n-type barrier region 13 and reach the intermediate portion of the n⁻-type base region 1 i.e., they extend into, but not through, the n⁻-type base region 1. Due to the formation of the emitter trenches 10, additional recessed portions are formed on the p-type base region 2, the n-type barrier region 13 and the n⁻-type base region 1.

In this embodiment, a depth (a length in the Z direction) of the emitter trenches 10 is substantially equal to a depth (a length in the Z direction) of the gate trenches 4. In the explanation made hereinafter, the description “substantially equal” includes the case where the depths of both trenches 10, 4 are equal in a range of the tolerance in manufacture in addition to the case where the depths of both trenches 10, 4 are physically the same. In this embodiment, the position of lower ends 6b of the gate electrodes 6 in the Z direction is substantially equal to the position of lower ends 12b of the conductive portions 12 in the Z direction.

A semiconductor material (polycrystalline silicon, for example) which is doped with a dopant is used for forming the conductive portions 12, for example. Metal may also be used for forming the conductive portions 12. In the semiconductor device 110, one gate electrode 6 and a set of n conductive portions 12 are arranged in sequence in the X direction.

The p-type base region 2 is formed on the n⁻-type base region 1, with n-type barrier region 13 therebetween. The p-type base region 2 is formed between the gate electrode 6 and the conductive portion 12, and between the plurality of conductive portions 12. In the embodiment shown in FIG. 1, the p-type base region 2 is formed between the first gate electrode 61 and the first conductive portion 121, between the first conductive portion 121 and the second conductive portion 122, and between the second conductive portion 122 and the second gate electrode 62.

The n⁺⁺-type emitter region 3 is formed on the p-type base region 2. The n⁺⁺-type emitter region 3 is formed on a portion of the p-type base region 2 adjacent to one side of each of the gate electrodes 6.

The n-type barrier region 13 is formed between the n⁻-type base region 1 and the p-type base region 2. In the example shown in FIG. 1, the n-type barrier region 13 is formed between the first gate electrode 61 and the first conductive portion 121, between the first conductive portion 121 and the second conductive portion 122, and between the second conductive portion 122 and the second gate electrode 62.

The p⁺-type collector region 8 is formed over the n⁻-type base region 1 on a side opposite to the p-type base region 2. An n⁺-type buffer region 7 may be formed between the p⁺-type collector region 8 and the n⁻-type base region 1. The n⁻-type base region 1 is laminated on the p⁺-type collector region 8 with the n⁺-type buffer region 7 sandwiched therebetween.

The gate insulation film 5 is formed between each of the plurality of gate electrodes 6 and the n⁻-type base region 1, the p-type base region 2, the n⁺⁺-type emitter region 3 and the n-type barrier region 13. The gate insulation film 5 is formed on an inner wall of the gate trench 4. The gate electrode 6 is formed in the gate trench 4 with the gate insulation film 5 interposed therebetween. The gate insulation film 5 is also formed over the gate electrode 6 between the gate electrode and the emitter electrode 9. A silicon oxide or a silicon nitride may be used for forming the gate insulation film 5, for example.

The emitter insulation film 11 is formed between each of the plurality of conductive portions 12 and the n⁻-type base region 1, the p-type base region 2 and the n-type barrier region 13. The emitter insulation film 11 is formed on an inner wall of the emitter trench 10. The conductive portion 12 is formed in the emitter trench 10 with the emitter insulation film 11 interposed therebetween. The emitter insulation film 11 is not formed over each of the conductive portions 12. A silicon oxide or a silicon nitride may be used for forming the emitter insulation film 11, for example.

The emitter electrode 9 is conductively connected with the p-type base region 2, the n⁺⁺-type emitter region 3 and the plurality of conductive portions 12. The emitter electrode 9 is formed over the whole surface of an upper portion of a structural body formed of the n⁻-type base region 1, the p-type base region 2, the n⁺⁺-type emitter region 3, the n-type barrier region 13, the p⁺-type collector region 8, the gate electrodes 6, and the conductive portions 12, for example. The gate insulation film 5 which is formed over the gate electrode 6 electrically insulates the gate electrode 6 from the emitter electrode 9. On the other hand, the emitter insulation film 11 is not formed on upper surfaces of the conductive portions 12. Accordingly, the emitter electrode 9 is brought into contact with the upper surfaces of the conductive portions 12 so that the emitter electrode 9 is conductively connected to the conductive portions 12. The emitter electrode 9 is also in conductive contact with the p-type base regions 2 located between the plurality of conductive portions 12.

The collector electrode 14 is conductively connected to the p⁺ collector region 8. The collector electrode 14 is formed on, for example, the whole surface of a lower portion of the structure formed of the n⁻-type base region 1, the p-type base region 2, the n⁺⁺-type emitter region 3, the n-type barrier region 13, the p⁺-type collector region 8, the gate electrodes 6, and the conductive portions 12.

In the semiconductor device 110 of this embodiment, silicon which is doped with a dopant (doped silicon) is used for forming the n⁻-type base region 1, the p-type base region 2, the n⁺⁺-type emitter region 3, the n-type barrier region 13, the p⁺-type collector region 8, and the n⁺-type buffer region 7, for example.

A dopant concentration in the n⁻-type base region 1 is approximately 1×10¹³ cm⁻³ or more and 1×10¹⁵ cm⁻³ or less, for example. A dopant concentration in the n-type barrier region 13 is higher than a dopant concentration in the n⁻-type base region 1. The dopant concentration in the n-type barrier region 13 is approximately 1×10¹⁷ cm⁻³ or less, for example.

A dopant concentration in the n⁺⁺-type emitter region 3 is higher than the dopant concentration in the n⁻-type base region 1 and the dopant concentration in the n-type barrier region 13. The dopant concentration in the n⁺⁺-type emitter region 3 is approximately 1×10¹⁸ cm⁻³ or more and 1×10²¹ cm⁻³ or less, for example.

A dopant concentration in the p-type base region 2 is approximately 1×10¹⁷ cm⁻³ or more and 1×10¹⁸ cm⁻³ or less, for example. A dopant concentration in the p⁺-type collector region 8 is higher than the dopant concentration in the p-type base region 2. The dopant concentration in the p⁺-type collector region 8 is approximately 1×10¹⁷ cm⁻³ or more and 1×10¹⁹ cm⁻³ or less, for example.

An interval between the plurality of gate electrodes 6 in the X direction (a distance between the centers of the gate electrodes 6) is approximately 1 μm or more and 20 μm or less, for example. A width of the gate electrode 6 is approximately 0.5 μm or more and 2.0 μm or less, for example. A length from a lower surface 9b of the emitter electrode 9 as a reference to the lower end 6b of the gate electrode 6 is approximately 1 μm or more and 6 μm or less, for example. A length of the conductive portion 12 from the lower surface 9b of the emitter electrode 9 which constitutes a reference to the lower end 12b is approximately 1 μm or more and 6 μm or less, for example.

An interval between the first gate electrode 61 and the first conductive portion 121 (a distance between the center of the first gate electrode 61 and the center of the first conductive portion 121) in the X direction is approximately 1 μm or more and 6 μm or less, for example. An interval between the plurality of conductive portions 12 (a distance between the centers of the conductive portions 12) in the X direction is approximately 1 μm or more and 6 μm or less, for example. A width of the conductive portion 12 is approximately 0.5 μm or more and 2.0 μm or less, for example.

A length of the n⁻-type base region 1 from the lower surface 9b of the emitter electrode 9 which constitutes a reference to the lower end 1b is approximately 50 μm or more and 500 μm or less, for example. A length of the p-type base region 2 from the lower surface 9b of the emitter electrode 9 which constitutes a reference to the lower end 2b is approximately 0.5 μm or more and 5.0 μm or less, for example. A length of the n⁺⁺-type emitter region 3 from the lower surface 9b of the emitter electrode 9 which constitutes a reference to a lower end 3b is approximately 2.0 μm or less, for example. A length of the n-type barrier region 13 in the Z direction is approximately 0.5 μm or more and 6 μm or less, for example.

A thickness (a length in the Z direction) of the p⁺ collector region 8 is approximately 0.1 μm or more and 3.0 μm or less, for example. A thickness (a length in the Z direction) of the n⁺-type buffer region 7 is approximately 30 μm or less, for example.

Next, the manner of operation of the semiconductor device 110 according to this embodiment is explained.

When a gate potential of a threshold value or more is applied to the gate electrode 6 in a state where a high potential is applied to the collector electrode 14 and a low potential lower than a potential of the collector electrode 14 is applied to the emitter electrode 9, an inversion layer (channel) is formed on the p⁺-type base region 2 in the vicinity of an interface with the gate insulation film 5.

For example, a ground potential or a negative potential is applied to the emitter electrode 9, and a positive potential is applied to the gate electrode 6. A positive potential higher than a potential applied to the gate electrode 6 is applied to the collector electrode 14. Due to this arrangement of potential, electrons are injected into the p-type base region 2 from the n⁺⁺-type emitter region 3 through the channel so that the semiconductor device 110 is brought into an ON state.

At this point of time, holes are further injected into the n⁻-type base region 1 from the p⁺-type collector region 8. The holes injected into the n⁻-type base region 1 flow into the emitter electrode 9 through the p-type base region 2.

When the semiconductor device 110 is in an ON state, holes are injected into the n⁻-type base region 1 from the p⁺-type collector region 8 so that the conductivity modulation is generated, i.e., the resistance in the n⁻-type base region 1 is decreased.

On the other hand, when a gate potential lower than a threshold value is applied to the gate electrode 6, a channel is not formed on the p-type base region 2 in the vicinity of an interface with the gate insulation film 5 so that the semiconductor device 110 is maintained or brought into an OFF state.

When the semiconductor device 110 is in an OFF state, holes generated in the n⁻-type base region 1 are efficiently discharged to the emitter electrode 9 through the p-type base region 2 formed between the plurality of conductive portions 12 as no channel is formed therein. Due to such discharging of holes, holes generated in the n⁻-type base region 1 by a high electric field in an OFF state are effectively extracted, thus increasing the breakdown resistance (breakdown threshold voltage) of the device.

In the semiconductor device 110 according to this embodiment, the n-type barrier region 13 is formed directly below the p-type base region 2 and hence, when the semiconductor device 110 is in ON state, the storage of carriers in the n⁻-type base region 1 is accelerated. Accordingly, it is possible to improve the tradeoff relationship that a turnoff loss E_{off} is increased when a collector-emitter saturation voltage V_{CE(sat)} is lowered. Further, in the semiconductor device 110, the plurality of conductive portions 12 which are in electrically conductive contact with the emitter electrode 9 are formed between the first gate electrode 61 and the second gate electrode 62 and hence, a channel is not formed in the p-type base region 2 adjacent to the conductive portion 12 side thereof. Accordingly, as compared to a case where the gate electrode 6 is formed in all of the plurality of trenches, the channel capacity is reduced so that high speed switching can be achieved (hysteresis is significantly reduced).

### Second Embodiment

Next, a semiconductor device according to the second embodiment is explained.

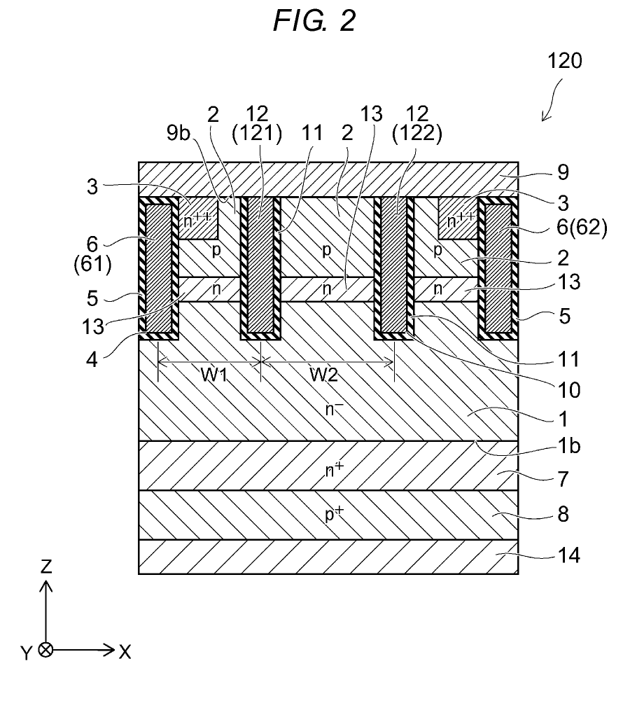

FIG. 2 is a schematic cross-sectional view of the semiconductor device according to a second embodiment.

As shown in FIG. 2, the semiconductor device 120 according to this embodiment differs from the semiconductor device 110 with respect to the distance or spacing between the gate electrode 6 and a conductive portion 12 and the distance or spacing between the adjacent ones of the plurality of the conductive portions 12. The remaining construct of the semiconductor device 120 is substantially the same as that of the semiconductor device 110 of the first embodiment (FIG. 1).

In the semiconductor device 120, the distance W2 between the plurality of conductive portions 12 in the X direction is larger than the distance W1 between the first gate electrode 61 and the first conductive portion 121 adjacent to the first gate electrode 61. When three or more conductive portions 12 are formed, it is sufficient that the distance between at least two (at least one distance between two conductive portions) of the plurality of conductive portions 12 is larger than the distance W1 between the first gate electrode 61 and the first conductive portion 121.

In the semiconductor device 120 having such a construction, when a reverse bias is applied to the semiconductor device 120, an electric field in the vicinity of the conductive portion 12 where the distance between the conductive portions 12 is larger than the distance between the conductive portion 12 and the first gate electrode 6 is stronger than the electric field in the vicinity of the gate electrode 6. Accordingly, an avalanche breakdown occurs between the plurality of conductive portions 12 where the larger distance is formed. Due to the occurrence of the avalanche breakdown, a hole current is extracted to the emitter electrode 9 through the region between the plurality of conductive portions 12 so that the concentration of electric current to any particular portion of the device is suppressed. In the semiconductor device 120, while a switching speed can be increased in the same manner as the semiconductor device 110, breakdown resistance is also enhanced.

### Third Embodiment

Next, a semiconductor device according to the third embodiment is explained.

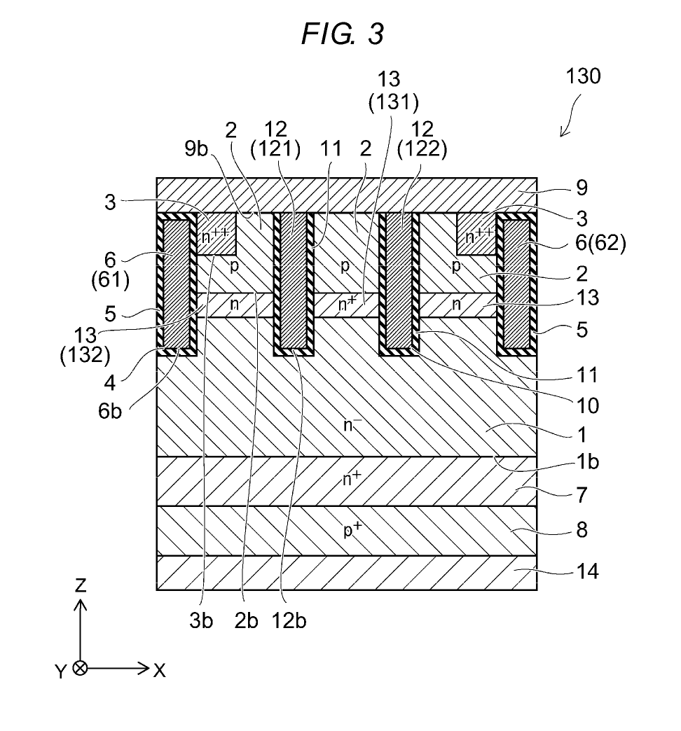

FIG. 3 is a schematic cross-sectional view of the semiconductor device according to the third embodiment.

As shown in FIG. 3, the semiconductor device 130 according to this embodiment differs from the semiconductor device 110 of the first embodiment with respect to a balance between a dopant concentration in an n-type barrier region 13 formed between a gate electrode 6 and a conductive portion 12 and a dopant concentration in an n-type barrier region 13 formed between a plurality of the conductive portions 12. Other portions of the semiconductor device 130 are substantially equal to the corresponding constitutions of the semiconductor device 110.

In the semiconductor device 130, the n-type barrier region 13 includes a first portion 131 formed between the plurality of conductive portions 12 and a second portion 132 formed between the first gate electrode 61 and the first conductive portion 121. A dopant concentration in the first portion 131 is higher than a dopant concentration in the second portion 132. When three or more conductive portions 12 are formed, it is sufficient that at least one n-type barrier region 13 out of the plurality of n-type barrier regions 13 formed between the plurality of conductive portions 12 has the higher dopant concentration.

The dopant concentration in the first portion 131 is approximately 1×10¹⁸ cm⁻³ or less, for example. The dopant concentration in the second portion 132 is approximately 1×10¹⁷ cm⁻³ or less, for example.

In the semiconductor device 130 so configured, when a reverse bias is applied to the semiconductor device 130, an electric field in the vicinity of the conductive portion 12 becomes stronger than an electric field in the vicinity of the gate electrode 6. Accordingly, an avalanche breakdown occurs between the plurality of conductive portions 12. Due to the occurrence of the avalanche breakdown, a hole current is extracted to the emitter electrode 9 through between the plurality of conductive portions 12 so that the concentration of electric current in any particular portion of the device is suppressed. In the semiconductor device 130, while a switching speed can be increased in the same manner as the semiconductor device 110, breakdown resistance is also enhanced.

### Fourth Embodiment

Next, a semiconductor device according to the fourth embodiment is explained.

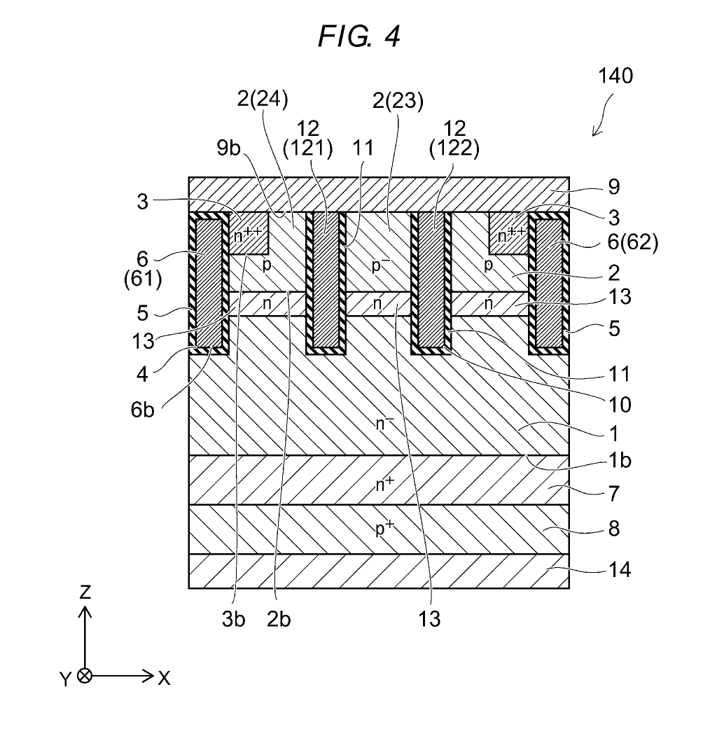

FIG. 4 is a schematic cross-sectional view of the semiconductor device according to the fourth embodiment.

As shown in FIG. 4, the semiconductor device 140 according to this embodiment differs from the semiconductor device 110 of the first embodiment with respect to a balance between a dopant concentration in a p-type base region 2 between a gate electrode 6 and a conductive portion 12 and a dopant concentration in the p-type base region 2 between a plurality of the conductive portions 12. Other portions of the semiconductor device 140 are substantially the same as the corresponding portions of the semiconductor device 110.

In the semiconductor device 140, the p-type base region 2 includes a third portion 23 formed between at least two of the plurality of conductive portions 12, and a fourth portion 24 formed between the first gate electrode 61 and the first conductive portion 121. A dopant concentration in the third portion 23 is lower than a dopant concentration in the fourth portion 24. When three or more conductive portions 12 are formed, it is sufficient that at least one p-type base region 2 out of the plurality of p-type base regions 2 formed between the plurality of conductive portions 12 is configured and doped as the third portion 23.

The dopant concentration in the third portion 23 is approximately 1×10¹⁷ cm⁻³ or less, for example. The dopant concentration in the fourth portion 24 is approximately 1×10¹⁷ cm⁻³ or more and 1×10¹⁸ cm⁻³ or less, for example, but greater than the dopant concentration on the third portion 23.

In the semiconductor device 140 having such a construct, when a reverse bias is applied to the semiconductor device 140, the electric field in the vicinity of the conductive portion 12 is stronger than the electric field in the vicinity of the gate electrode 6. Accordingly, avalanche breakdown occurs between the plurality of conductive portions 12. Due to the occurrence of the avalanche breakdown, a hole current is extracted to the emitter electrode 9 through the region between the plurality of conductive portions 12 so that the concentration of electric current to any particular portion of the device is suppressed. In the semiconductor device 140, while a switching speed can be increased in the same manner as the semiconductor device 110, breakdown resistance can be also enhanced.

### Fifth Embodiment

Next, a semiconductor device according to the fifth embodiment is explained.

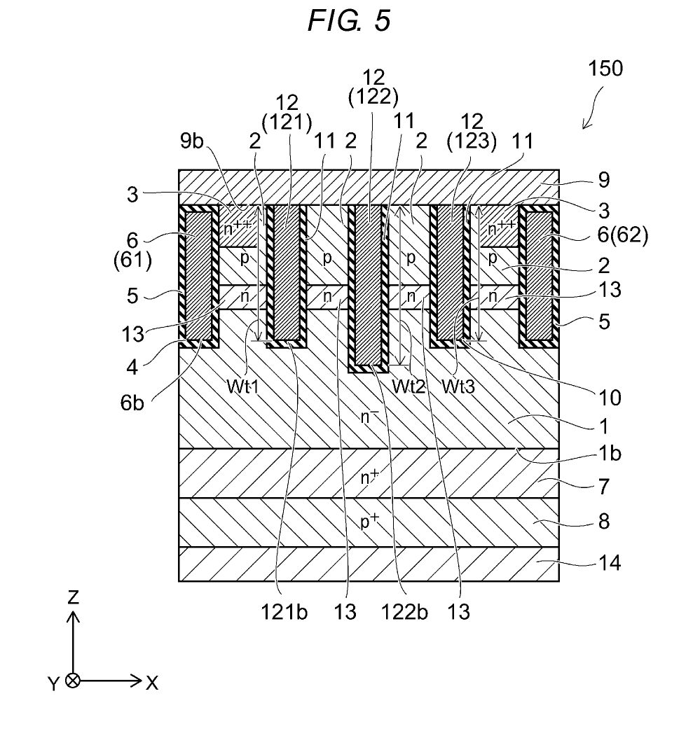

FIG. 5 is a schematic cross-sectional view of the semiconductor device according to the fifth embodiment.

As shown in FIG. 5, in the semiconductor device 150 according to this embodiment, three or more conductive portions 12 are formed, and a technical feature lies in a balance between lengths of these conductive portions 12, i.e., the extent to which they extend into the n⁻-type base region 1. Other features of the semiconductor device 150 are substantially the same in construct as the corresponding features of the semiconductor device 110.

In the example shown in FIG. 5, the plurality of conductive portions 12 include a first conductive portion 121 adjacent to a first gate electrode 61, a third conductive portion 123 adjacent to a second gate electrode 62, and a second conductive portion 122 formed between the first conductive portion 121 and the third conductive portion 123. A depth (a length in the Z direction) Wt2 of the second conductive portion 122 is larger than a depth (a length in the Z direction) Wt1 of the first conductive portion 121 and a depth (a length in the Z direction) Wt3 of the third conductive portion 123 as measured from the top of the emitter electrode 9 and the extent to which the conductive portions 121, 122 and 123 extend inwardly of the n⁻-type base region 1.

When a lower surface 9b of an emitter electrode 9 is set as a reference, a length of the second conductive portion 122 from the emitter electrode 9, or the top of the interface of n-type barrier region 13 and the n⁻-type base region 1 to a lower end 122b thereof is longer than a length of a gate electrode 6 from the emitter electrode 9, or the top of the interface of n-type barrier region 13 and the n⁻-type base region 1 to a lower end 6b thereof. The length of the first conductive portion 121 from the lower surface 9b of the emitter electrode 9 to the lower end 121b thereof is substantially equal to the combined length of the gate electrode 6 to the lower end 6b thereof and the thickness of the gate insulating film 5 formed over the gate electrode 6 between the gate electrode 6 and the emitter electrode 9. The length of the third conductive portion 123 from the lower surface 9b of the emitter electrode 9 to the lower end 123b thereof is substantially equal to the combined length of the gate electrode 6 extending to the lower end 6b thereof and the thickness of the gate insulating film 5 formed over the gate electrode 6 between the gate electrode 6 and the emitter electrode 9.

In the semiconductor device 150 of this fifth embodiment, a depth of the conductive portion 12 (122) which is not adjacent to the gate electrode 6 is greater than the depth of the conductive portions 12 (121, 123) adjacent to the gate electrodes 6. When a plurality of conductive portions 12 which are not adjacent to the gate electrode 6, i.e., are between adjacent conductive portions 12, are formed, it is sufficient that at least one depth out of depths of these conductive portions 12 is larger than the depth of the conductive portion 12 adjacent to the gate electrode 6.

In the semiconductor device 150 having such a construction, when a reverse bias is applied to the semiconductor device 150, the electric field in the vicinity of the conductive portion 12 is stronger than the electric field in the vicinity of the gate electrode 6. Accordingly, avalanche breakdown occurs between the plurality of conductive portions 12, primarily between conductive portion 122 and conductive portion 121 or 123. Due to the occurrence of the avalanche breakdown, a hole current is extracted to the emitter electrode 9 through the region between the plurality of conductive portions 12, e.g., between conductive portion 122 and conductive portion 121 or 123, so that the concentration of electric current to any particular portion is suppressed. In the semiconductor device 150, while a switching speed can be increased in the same manner as the semiconductor device 110, breakdown resistance can be also enhanced.

### Sixth Embodiment

Next, a semiconductor device according to the sixth embodiment is explained.

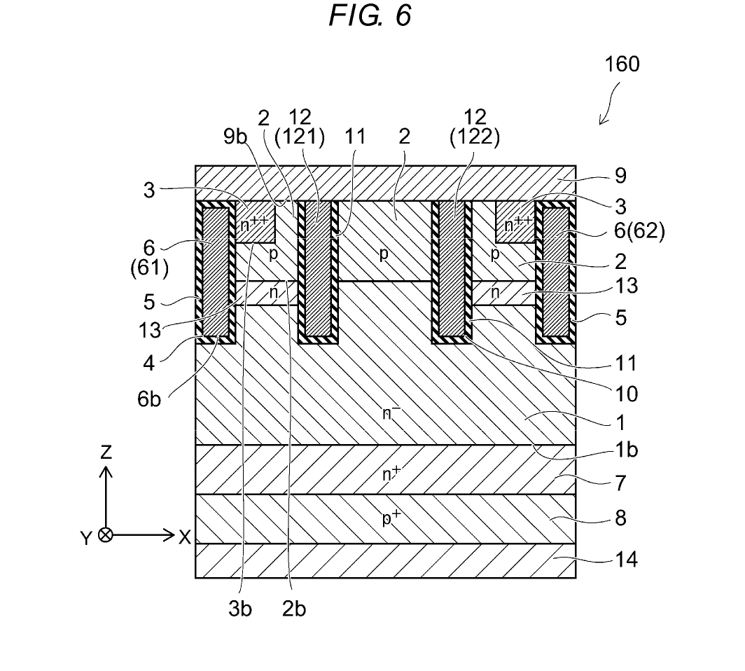

FIG. 6 is a schematic cross-sectional view of the semiconductor device according to the sixth embodiment.

As shown in FIG. 6, a semiconductor device 160 according to this embodiment differs from the semiconductor device 110 with respect to the structure of the doped layers extending between a the conductive portions 12. Other features of the semiconductor device 160 are substantially equal to the corresponding features of the semiconductor device 110.

In the semiconductor device 160, a p-type base region 2 is provided between the plurality of conductive portions 12 and is in contact with an n⁻-type base region 1. That is, an n-type barrier region 13 is not provided between the p-type base region 2 extending between adjacent conductive portions 12 and the n⁻-type base region 1. When three or more conductive portions 12 are formed, it is sufficient that at least one p-type base region 2 out of the p-type base regions 2 formed between at least two of the conductive portions 12 is in direct contact with the n⁻-type base region 1, i.e., without an intervening n-type barrier region 13.

In the semiconductor device 160 having such a construct, a residual carrier comes out from the p-type base region 2 between the plurality of conductive portions 12 immediately after a reverse bias is applied to the semiconductor device 160 so that when a reverse bias is applied to the semiconductor device 160, the electric field in the vicinity of the conductive portion 12 is stronger than an electric field in the vicinity of the gate electrode 6. Accordingly, an avalanche breakdown occurs in the regions between the plurality of conductive portions 12, primarily between conductive portion 121 and conductive portion 122. Due to the occurrence of the avalanche breakdown, a hole current is extracted to the emitter electrode 9 through between the plurality of conductive portions 12 so that the concentration of electric current to any particular portion is suppressed. In the semiconductor device 160, while the switching speed can be increased in the same manner as the semiconductor device 110, breakdown resistance of the device is also enhanced.

### Seventh Embodiment

Next, a semiconductor device according to the seventh embodiment is explained.

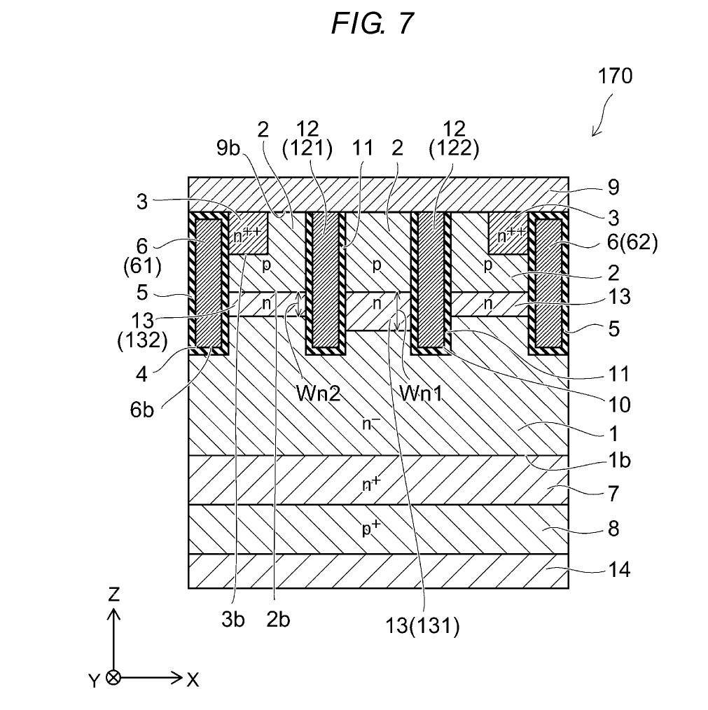

FIG. 7 is a schematic cross-sectional view of the semiconductor device according to the seventh embodiment.

As shown in FIG. 7, a semiconductor device 170 according to this embodiment differs from the semiconductor device 110 with respect to the depth of an n-type barrier region 13 formed between a gate electrode 6 and a conductive portion 12 and the depth of an n-type barrier region 13 formed between a plurality of the conductive portions 12. Other portions of the semiconductor device 170 are substantially equal to the corresponding portions of the semiconductor device 110.

In the semiconductor device 170, the n-type barrier region 13 includes a first portion 131 formed between the conductive portions 12 and a second portion 132 formed between the first gate electrode 61 and the first conductive portion 121. A depth (a length in the Z direction) Wn1 of the first portion 131 is larger than a depth (a length in the Z direction) Wn2 of the second portion 132. When three or more conductive portions 12 are formed, it is sufficient that at least one n-type barrier region 13 out of the n-type barrier regions 13 formed between at least two of the plurality of conductive portions 12 be configured as the greater thickness, deeper extending, e first portion 131.

The depth Wn1 of the first portion 131 is approximately 6 μm or less, for example. The depth Wn2 of the second portion 132 is approximately 1 μm or more and 5 μm or less, for example.

In the semiconductor device 170 having such a construction, when a reverse bias is applied to the semiconductor device 170, an electric field in the vicinity of the conductive portion 12 becomes stronger than an electric field in the vicinity of the gate electrode 6. Accordingly, avalanche breakdown occurs between the plurality of conductive portions 12. Due to the occurrence of the avalanche breakdown, a hole current is extracted to the emitter electrode 9 through the region between the plurality of conductive portions 12 so that the concentration of electric current to any particular portion is suppressed. In the semiconductor device 170, while a switching speed can be increased in the same manner as the semiconductor device 110, breakdown resistance can be also enhanced.

### Eighth Embodiment

Next, a semiconductor device according to the eighth embodiment is explained.

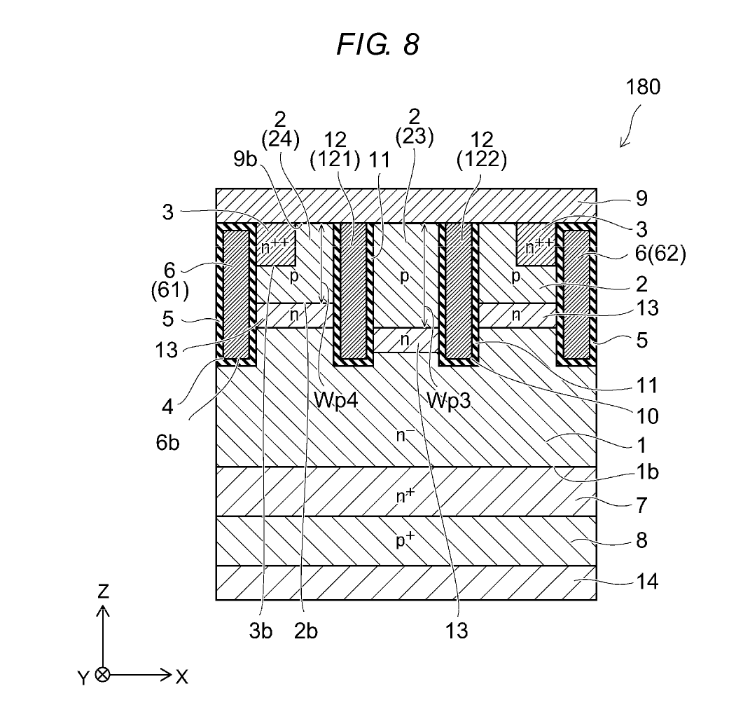

FIG. 8 is a schematic cross-sectional view of the semiconductor device according to the eighth embodiment.

As shown in FIG. 8, a semiconductor device 180 according to this embodiment differs from the semiconductor device 110 with respect to the depth (thickness) of a p-type base region 2 between a gate electrode 6 and a conductive portion 12 and the depth (thickness) of a p-type base region 2 between at least two of the plurality of conductive portions 12. Other portions of the semiconductor device 180 are substantially equal to the corresponding portions of the semiconductor device 110.

In the semiconductor device 180 of this embodiment, the p-type base region 2 includes a third portion 23 formed between adjacent conductive portions 12 and a fourth portion 24 formed between a first gate electrode 61 and a first conductive portion 121. A depth (a length or thickness in the Z direction) Wp3 of the third portion 23 is larger than a depth (a length or thickness in the Z direction) Wp4 of the fourth portion 24. When three or more conductive portions 12 are formed, it is sufficient that at least one thicker p-type base region 2 out of the p-type base regions 2 formed between the plurality of conductive portions 12 is provided as the third portion 23.

The depth Wp3 of the third portion 23 is approximately 6 μm or less, for example. The depth Wp4 of the fourth portion 24 is approximately 1 μm or more and 5 μm or less, for example.

In the semiconductor device 180 having such a constitution, when a reverse bias is applied to the semiconductor device 180, the electric field in the vicinity of the conductive portion 12 is stronger than an electric field in the vicinity of the gate electrode 6. Accordingly, an avalanche breakdown occurs in the region between the plurality of conductive portions 12. Due to the occurrence of the avalanche breakdown, a hole current is extracted to the emitter electrode 9 in the region between the conductive portions 12 so that the concentration of electric current to any particular portion is suppressed. In the semiconductor device 180, while a switching speed can be increased in the same manner as the semiconductor device 110, breakdown resistance of the device can be also enhanced.

### Ninth Embodiment

Next, a semiconductor device according to the ninth embodiment is explained.

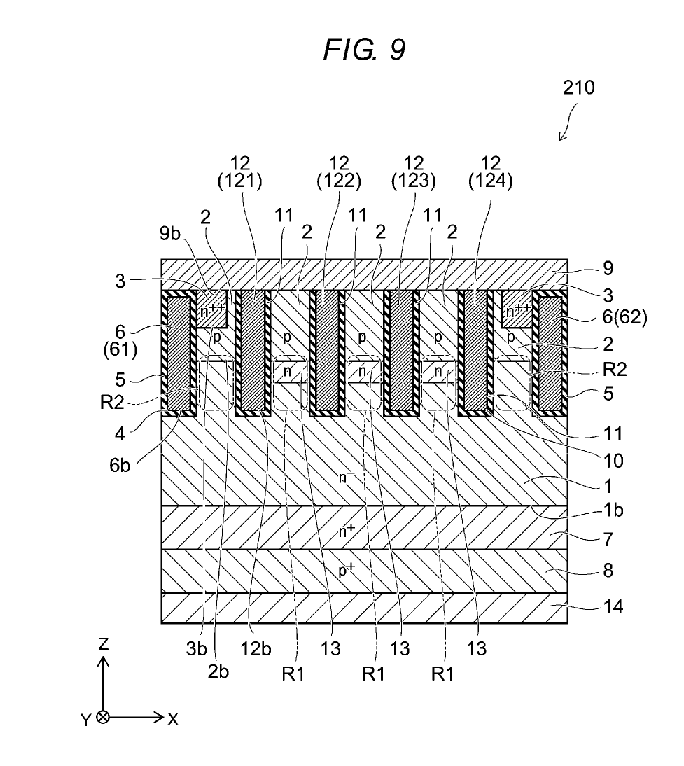

FIG. 9 is a schematic cross-sectional view of the semiconductor device according to the ninth embodiment.

As shown in FIG. 9, in a semiconductor device 210 according to this embodiment, two or more conductive portions 12 are formed between a first gate electrode 61 and a second gate electrode 62. In the semiconductor device 210, an n-type barrier region 13 is formed between the plurality of conductive portions 12. On the other hand, the n-type barrier region 13 is not formed between a gate electrode 6 and the conductive portion 12. That is, an n⁻-type base region 1 is brought into contact with a p-type base region 2 between the gate electrode 6 and the conductive portion 12.

In the embodiment of the semiconductor device 210 shown in FIG. 9, four conductive portions 12 including a first conductive portion 121, a second conductive portion 122, a third conductive portion 123 and a fourth conductive portion 124 are formed. Due to such formation of the conductive portions 12, three first regions R1 are formed between the four conductive portions 12. A second region R2 is formed between the first gate electrode 61 and the first conductive portion 121, and between the second gate electrode 62 and the fourth conductive portion 124.

In the semiconductor device 210, in each of the plurality of first regions R1, an n-type barrier region 13 is formed between an n⁻-type base region 1 and a p-type base region 2. On the other hand, the n-type barrier region 13 is not formed in the second region R2. In the second region R2, the n⁻-type base region 1 and the p-type base region 2 are in contact with each other.

In the semiconductor device 210 having such a construction, the n-type barrier region 13 is formed on the first region R1 and the n-type barrier region 13 is not formed on the second region R2 so that when a reverse bias is applied to the semiconductor device 210, the electric field in the vicinity of the conductive portions 12 becomes stronger than an electric field in the vicinity of the gate electrode 6. Accordingly, an avalanche breakdown occurs in the vicinity of the conductive portions 12. Due to the occurrence of the avalanche breakdown, a hole current is extracted to the emitter electrode 9 through between the conductive portions 12 so that the concentration of electric current to any particular portion is suppressed. In the semiconductor device 210, in addition to the increase of a switching speed in the same manner as the semiconductor device 110 of the first embodiment, enhancement of the breakdown voltage is also achieved.

### Tenth Embodiment

Next, a semiconductor device according to the tenth embodiment is explained.

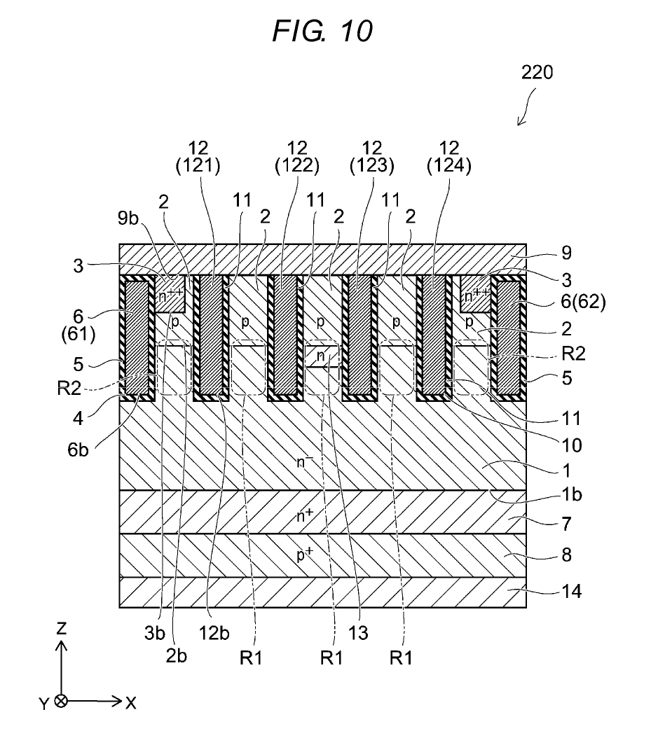

FIG. 10 is a schematic cross-sectional view of the semiconductor device according to the tenth embodiment.

As shown in FIG. 10, in a semiconductor device 220 according to this embodiment, three or more conductive portions 12 are formed between a first gate electrode 61 and a second gate electrode 62. Due to the formation of the conductive portions 12, a plurality of first regions R1 are formed between the plurality of conductive portions 12. In the semiconductor device 220 of this tenth embodiment, an n-type barrier region 13 is formed on at least one of a plurality of first regions R1. On the other hand, the n-type barrier region 13 is not formed between a gate electrode 6 and the conductive portion 12. That is, between the gate electrode 6 and the conductive portion 12, an n⁻-type base region 1 is in contact with a p-type base region 2.

In the semiconductor device 220 of the example shown in FIG. 10, four conductive portions 12 including a first conductive portion 121, a second conductive portion 122, a third conductive portion 123 and a fourth conductive portion 124 are formed. Due to the formation of the four conductive portions 12, three first regions R1 are formed between the four conductive portions 12. A second region R2 is formed between the first gate electrode 61 and the first conductive portion 121, and between the second gate electrode 62 and the fourth conductive portion 124 respectively.

In the semiconductor device 220, in one of the three first regions R1, the n-type barrier region 13 is formed between the n⁻-type base region 1 and the p-type base region 2. In the example shown in FIG. 10, the n-type barrier region 13 is formed on the first region R1 formed between the second conductive portion 122 and the third conductive portion 123. That is, the n-type barrier region 13 is formed on the center first region R1 out of the three first regions R1.

On the other hand, the n-type barrier region 13 is not formed on the first region R1 formed between the first conductive portion 121 and the second conductive portion 122, and in the first region R1 formed between the third conductive portion 123 and the fourth conductive portion 124. The n-type barrier region 13 is not formed either in the second region R2. In the first region R1 and the second region R2 in which the n-type barrier region 13 is not formed, the n⁻-type base region 1 and the p-type base region 2 are brought into contact with each other.

In the semiconductor device 220 having such a construction, the n-type barrier region 13 is formed on at least one of the plurality of first regions R1, and the n-type barrier region 13 is not formed on other first regions R1 and the second region R2 and hence, when a reverse bias is applied to the semiconductor device 220, an electric field in the vicinity of the conductive portion 12 adjacent to the first region R1 in which the n-type barrier region 13 is formed becomes stronger than an electric field in the vicinity of the gate electrode 6.

Accordingly, an avalanche breakdown occurs in the vicinity of the conductive portion 12 adjacent to the first region R1 in which the n-type barrier region 13 is formed. Due to the occurrence of the avalanche breakdown, a hole current is extracted to the emitter electrode 9 through the region between the plurality of conductive portions 12 adjacent to the first region R1 in which the n-type barrier region 13 is formed so that the concentration of electric current to any particular portion is suppressed. In the semiconductor device 220, in addition to the increase of a switching speed in the same manner as the semiconductor device 110, the enhancement of the breakdown voltage is also achieved.

When the plurality of first regions R1 are formed, it is desirable that n-type barrier regions 13 are symmetrically arranged with respect to the center of a location where the plurality of first regions R1 are formed. Due to such arrangement of the n-type barrier regions 13, avalanche breakdown easily occurs at portions equally spaced from the first gate electrode 61 and the second gate electrode 62 so that breakdown resistance can be enhanced.

In the example shown in FIG. 10, the case where the n-type barrier region 13 is formed on one of the plurality of first regions R1 is explained. However, the n-type barrier region 13 may be formed on two or more first regions R1, and preferably symmetrically with respect to the mid-point of the plurality of conductors 9, such as all three regions R1 in FIG. 10, only the center region R1 as shown in FIG. 10, or only the right and left of the three regions shown in FIG. 10.

As has been explained above, according to the semiconductor device of the embodiments, high-speed switching can be acquired.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first region of a first conductivity type;
a collector electrode electrically connected to a first side of the first region;
first and second gate electrodes and first and second conductor electrodes, each of the gate and conductor electrodes extending into the first region from a second side thereof that is opposite to the first side;
an emitter electrode electrically connected to the conductor electrodes; and
a second region of the first conductivity type, that is adjacent to the gate electrodes, electrically connected to the emitter electrode, and spaced from the first and second conductor electrodes.

2. The semiconductor of claim 1, wherein a distance between the first and second conductor electrodes is greater than that between the first gate electrode and the first conductor electrode, and greater than that between the second gate electrode and the second conductor electrode.

3. The semiconductor device of claim 1, further comprising:
a third region of the first conductivity type interposed between the first region of the first conductivity type and the second region of the first conductivity type and between one of the gate electrodes and one of the conductor electrodes.

4. The semiconductor device of claim 3, further comprising:
a first region of a second conductivity type in electrical contact with the emitter electrode and interposed between the third region of the first conductivity type and the emitter electrode; and
a second region of the second conductivity type in electrical contact with the emitter electrode and interposed between the first region of the first conductivity type and the emitter electrode and between the first and second conductor electrodes.

5. The semiconductor device of claim 3, further comprising:
a fourth region of the first conductivity type interposed between the first region of the first conductivity type and the second region of the first conductivity type and between the conductor electrodes.

6. The semiconductor device of claim 5, wherein a dopant concentration of the third region of the first conductivity type is equal to that of the fourth region of the first conductivity type.

7. The semiconductor device of claim 5, wherein a dopant concentration of the third region of the first conductivity type is less than that of the fourth region of the first conductivity type.

8. The semiconductor device of claim 5, further comprising:
a first region of a second conductivity type in electrical contact with the emitter electrode and interposed between the third region of the first conductivity type and the emitter electrode; and
a second region of the second conductivity type in electrical contact with the emitter electrode and interposed between the fourth region of the first conductivity type and the emitter electrode.

9. The semiconductor device of claim 8, wherein a dopant concentration of the first region of the second conductivity type is equal to that of the second region of the second conductivity type.

10. The semiconductor device of claim 8, wherein a dopant concentration of the first region of the second conductivity type is greater than that of the second region of the second conductivity type.

11. The semiconductor device of claim 8, wherein the third region of the first conductivity type is separated from the emitter electrode by a shorter distance than the fourth region of the first conductivity type.

12. The semiconductor device of claim 8, wherein the first region of the second conductivity type is separated from the first region of the first conductivity type by a shorter distance than the second region of the second conductivity type.

13. The semiconductor device of claim 1, further comprising:
a third conductor electrode extending into the first region from the second side thereof between the first and second conductor electrodes.

14. The semiconductor device of claim 13, wherein the third conductor electrode extends farther into the first region than the first and second conductor electrodes.

15. A semiconductor device comprising:
a first semiconductor region;
a plurality of control and conductive electrodes, each extending into a surface of the first semiconductor region;
a second semiconductor region on the first semiconductor region;
a third semiconductor region on the second semiconductor region;
a fourth semiconductor region between the first semiconductor region and the second semiconductor region;
a fifth semiconductor region on a side of the first semiconductor region opposite to the second semiconductor region;
a first electrode electrically connected to the second semiconductor region, the third semiconductor region, and the conductive electrodes; and
a second electrode electrically connected to the fifth semiconductor region,
wherein the first, third, and fourth semiconductor regions have a first conductivity type and the second and fifth semiconductor regions have a second conductivity type.

16. The semiconductor device of claim 15, further comprising:
a first insulation film between the control electrodes and each of the first semiconductor region, the second semiconductor region, the third semiconductor region, and the first electrode; and
a second insulation film between the conductive electrodes and each of the first semiconductor region, and the second semiconductor region.

17. The semiconductor device of claim 15, wherein first portions of the second semiconductor region are spaced from the first semiconductor region by the fourth semiconductor region and second portions of the second semiconductor region directly contact the first semiconductor region.

18. The semiconductor device of claim 17, wherein first portions of the second semiconductor region are disposed between pairs of the conductor electrodes.

19. The semiconductor device of claim 17, wherein second portions of the second semiconductor region are disposed between one of the control electrodes and one of the conductor electrodes.

20. The semiconductor device of claim 19, wherein second portions of the second semiconductor region are additionally disposed between the conductor electrodes.
